(19) United States
(12) Patent Application Publication
(10) Pub. No.: US 2007/0264796 A1
(43) Pub. Date: Nov. 15, 2007

(54) Method for forming a semiconductor on insulator structure

(76) Inventor: Mark Andrew Stocker, Painted Post, NY (US)

Correspondence Address: CORNING INCORPORATED, SP-TI-3-1, CORNING, NY, 14831, US

(21) Appl. No.: 11/433,086

(22) Filed: May 12, 2006

(51) Int. Cl. H01L 21/46; H01L 29/06

(52) U.S. Cl. 438/455; 438/458; 257/618

(57) ABSTRACT

A method of bonding a thin semiconductor film onto a rectangular substrate is disclosed. The method makes it possible to exfoliate rectangular semiconductor films from a round precursor semiconductor wafer, thereby providing for efficient tiling of the substrate with semiconductor film. The method includes the steps of creating a damage zone in the precursor wafer by ion implantation of the wafer, removing a portion of the wafer to formed a raised portion, bonding the raised portion of the wafer to the substrate, and exfoliating the bonded raised portion.

### BACKGROUND OF THE INVENTION

1. Field of the Invention

This invention is directed to a method of forming a semiconductor-on-insulator structure, and in particular, a silicon-on-glass structure.

2. Technical Background

The economic manufacture of silicon wafers used for the production of semiconductor devices is well known. All such wafers are thin round discs, and semiconductor manufacturing systems have been optimized for the production of thin round discs. The current standard size for silicon wafers is approximately 300 mm in diameter.

Flat display glass panels, such as those used in the manufacture of liquid crystal displays for example, require thin films of silicon to be deposited upon them in order to produce the semiconductor pixel switches. One method of performing this deposition is by transferring exfoliated, thin films from a prime silicon wafer onto the display glass.

Prior to exfoliation, the wafers are ion implanted to produce a damage layer beneath the polished wafer surface. The wafer is bonded to the display glass and the thin film exfoliated along a fracture plane that forms from the ion implantation layer.

Exfoliation thickness uniformity is critically dependent upon the wafer face surface texture uniformity prior to the ion implantation. Wafer surfaces of prime semiconductor polish quality are required for uniform implantation and exfoliation.

To maximize the area of silicon available to produce rectangular display panels the deposited silicon film should also be rectangular. Further, in order to be economically viable, the wafers used to deposit the film must be capable of being re-used many times. This will require the wafer to be re-polished and re-implanted in preparation for another exfoliation process.

Semiconductor devices are usually square or rectangular, yet they are always manufactured on round wafers, resulting in significant wafer waste. This level of waste is tolerated within the semiconductor arts because the advantages of manufacturing round wafers vs. rectangular wafers outweighs the cost associated with the wasted material.

To maximize flat panel yield, the rectangular semiconductor films must be as large as possible, typically the largest possible single tile able to be produced from standard wafers (typically diameters of 100 mm, 150 mm, 200 mm and 300 mm), and are tiled across the surface of the flat panel substrate. Ideally, because the flat glass panel used in the manufacture of flat panel display devices is rectangular, the semiconductor tiles would also be rectangular. But even if rectangular semiconductor wafers were available, uniformity of the polished surface would be difficult to achieve.

Polishing uniformity is maintained in round wafers by rotating the round wafer relative to a round polishing pad. Surface texture and wafer thickness control are maintained by the averaging effect of a round wafer polished by a round pad. All areas of the wafer experience the same pressure and time in contact with the polishing pad.

If a rectangular wafer is polished, the pressure and time in contact with the polishing pad across the whole surface is more variable than with a round wafer, especially at the corners, where the wafer tends to be preferentially machined, resulting in wafer thickness and surface texture non-uniformity. Thus, what is needed is a method of forming and transferring a rectangular-shaped, thin semiconductor film from a round semiconductor wafer to the rectangular glass panel.

### SUMMARY

In one embodiment of the present invention, an SOI structure is formed by providing a wafer comprising silicon, ion implanting the silicon wafer, removing portions of the silicon wafer to form a raised portion, bonding the raised portion to the substrate and separating the raised portion from the wafer to form the semiconductor film on the substrate.

In another embodiment, a method of forming a semiconductor film on a substrate is presented comprising forming a separation zone in a semiconductor wafer, removing a portion of the semiconductor wafer to form a raised portion, anodically bonding the raised portion to the glass substrate, separating the raised portion from the wafer. The bonding comprises restraining edges of the wafer and pressing the raised portion into contact with the substrate.

In still another embodiment an SOI structure is formed by:

a. providing a circular semiconductor wafer having at least one substantially planar first surface and a second surface opposite the first surface;

b. forming a defect boundary within the wafer at a predetermined depth from the wafer first surface by ion implantation;

c. removing material from the wafer such that a raised, rectangular region is formed on the first surface of the wafer;

d. positioning the wafer over a planar substrate such that a surface of the raised rectangular region is substantially parallel with a surface of the substrate;

e. restraining edges of the wafer;

f. contacting the raised rectangular region with the silicon wafer by forcing a heater plate against the wafer second surface;

g. bonding the raised rectangular region to the substrate by anodic bonding;

h. separating the wafer along the defect boundary, thereby forming a semiconductor layer on the substrate.

The invention will be understood more easily and other objects, characteristics, details and advantages thereof will become more clearly apparent in the course of the following explanatory description, which is given, without in any way implying a limitation, with reference to the attached Figures. It is intended that all such additional systems, methods features and advantages be included within this description, be within the scope of the present invention, and be protected by the accompanying claims.

### BRIEF DESCRIPTION OF THE DRAWINGS

FIG. 1 is a cross sectional view of a semiconductor wafer showing the damage or separation zone and the land portion of the wafer which will be bonded and exfoliated to a substrate.

FIG. 2 is a perspective view of the wafer of FIG. 1 showing portions of the wafer removed to produce the land portion.

FIG. 3 is a cross sectional view of the land portion of the wafer of FIG. 2 being put in contact with the substrate and bonded thereto.

FIG. 4 is a perspective view of an additional semiconductor film being bonded to the substrate in the manner of FIG. 3 to tile the substrate with semiconductor films.

### DETAILED DESCRIPTION

In the following detailed description, for purposes of explanation and not limitation, example embodiments disclosing specific details are set forth to provide a thorough understanding of the present invention. However, it will be apparent to one having ordinary skill in the art, having had the benefit of the present disclosure, that the present invention may be practiced in other embodiments that depart from the specific details disclosed herein. Moreover, descriptions of well-known devices, methods and materials may be omitted so as not to obscure the description of the present invention. Finally, wherever applicable, like reference numerals refer to like elements.

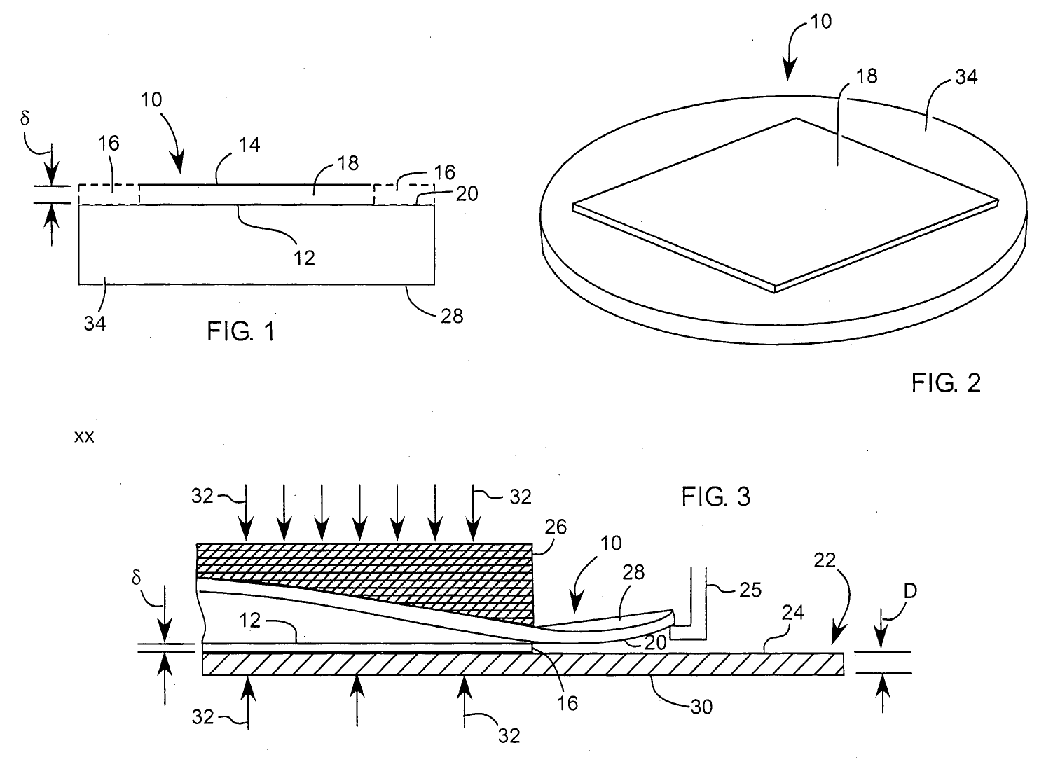

In accordance with an embodiment of the present invention, a method of transferring a rectangular shaped wafer of semiconductor material from a round precursor wafer is disclosed. Referring to FIGS. 1-2, a round semiconductor wafer 10 having substantially planar and parallel first and second surfaces is ion implanted according to known techniques to form a damage boundary 12 at a prescribed depth 6 below first surface 14 of round wafer 10. Portions 16 of the semiconductor wafer material are removed to a depth 6 corresponding to the depth 6 of damage boundary 12, leaving a portion 18 of the silicon wafer which has not had material removed extending to a height 6 above exposed surface 20. The portion extending above surface 14 will hereinafter be termed the land portion 18 of semiconductor wafer 10. Referring to FIG. 3, the ion-implanted semiconductor wafer 10 is then positioned over glass substrate 22 such that surface 14 of land portion 18 is in close proximity and substantially parallel to surface 24 of glass substrate 22. Edges of semiconductor wafer 10 are restrained, and heating element 26 is brought into contact with backside 28 of wafer 10. Heating element 26 is lowered against the backside second surface of wafer 10, forcing land portion 18 of semiconductor wafer 10 into contact with glass substrate 22. Through the action of heat, pressure, electrical potential (delivered by or through heating element/electrode 26) and time, surface 14 of land portion 16 is bonded to surface 24 of glass substrate 22. Once bonding is complete, heating element/electrode 26 is raised, and land portion 18 of semiconductor wafer 10 separates along damage boundary 12, leaving a thin film of semiconductor material bonded to the glass substrate. Details of this and other embodiments will be described in detail below.

A major challenge of using inexpensive materials as a support substrate and, in particular, using glass-based materials (e.g. oxide glasses and oxide glass-ceramics) as a support substrate is that most glasses comprising glass-based wafers cannot withstand the 1100° C. bonding treatment as conventionally used in the art. Thus, the covalent bonding between the glass-based layer and the semiconductor material, e.g., silicon, must be achieved at temperatures significantly lower than 1100° C. The requirement for lower temperatures also makes it challenging to separate the semiconductor wafer into parts at a damage boundary or separation zone formed by, for example, hydrogen ion implantation.

Moreover, when a glass-based material is substituted for silicon as a support substrate material, thermal expansion of the glass-based material should be matched to the thermal expansion of the semiconductor layer of the semiconductor on insulator (SOI) structure to avoid separation of the semiconductor layer from the insulating support substrate. Although some glass-based materials with thermal expansions close to that of semiconductor materials, e.g. silicon, are known, an exact match is nevertheless difficult to obtain. Thermal expansion mismatches are especially troublesome for large wafers where high stress can cause de-bonding of the semiconductor layer.

Thus, multiple problems must be addressed and overcome to provide SOI structures which employ support substrates composed of glass-based materials. Ion implantation and anodic bonding of the semiconductor material to the glass-based substrate has been found to address some of the problems described supra. A useful method for performing anodic bonding of semiconductor materials is described, for example, in U.S. application Ser. No. 10/779,582, filed on Feb. 12, 2004 and incorporated herein by reference in its entirety. For the purpose of clarity of presentation, the glass-based material will hereinafter be referred to as a glass substrate, with the understanding that reference is made also to other glass-based materials, such as glass-ceramics.

One problem which makes anodic bonding inefficient in its current practice, as described in U.S. application Ser. No. 10/779,582 is that most, if not all processes for producing boules of semiconductor material produce boules that are cylindrical in shape. Semiconductor wafers subsequently cut from the boules are therefore also round. Commercially available semiconductor wafers typically range in diameter from about 100 mm to 300 mm. On the other hand, display devices, e.g. computer monitors, flat panel televisions, and the like, are invariably rectangular and have surface areas reaching in some cases tens of thousands of square centimeters.

To recap briefly, in the hydrogen ion implantation process, hydrogen ions are implanted to a prescribed depth in the semiconductor wafer, the wafer is brought into contact with the glass substrate and anodic bonding is used to bond the wafer to the substrate. The wafer and substrate are cooled, and the wafer is then lifted off the substrate. The wafer fractures or cleaves along a defect boundary created by the ion implantation, leaving a thin film of semiconductor material bonded to the substrate. The cleaving of the semiconductor to leave a thin semiconductor film is sometimes referred to as exfoliation. The semiconductor wafer which was lifted from the substrate may then be surface finished, and the process begun again. That is, multiple semiconductor films are typically “tiled” onto the surface of the glass substrate to cover the substrate surface. Unfortunately, the implantation and bonding process just described leaves a circular film of semiconductor material on the substrate, making it difficult to completely cover the glass substrate with a semiconductor film.

The advantages of using a tiling process include the ability to provide large glass or glass-ceramic substrates with substantially single crystal semiconductor films without a limitation on size. For display applications, the size of the glass substrate needed is often larger than the 300 mm diameter of semiconductor wafers. Similarly, photovoltaic applications also require large area SOI structures.

Tiling also allows substantially single crystal semiconductor materials to be placed on desired sites on glass or glass-ceramic substrates. This ability allows placement of high performance semiconductor films, e.g., silicon films, in the areas of large substrates where drivers and memory circuits may be placed and thus avoids having to cover the entire substrate with a semiconductor film, thus reducing cost.

When multiple semiconductor substrates are tiled on a single glass or glass-ceramic substrate, the distance between the semiconductor films of the finished SOI structure depends on the proximity of the semiconductor substrates during initial assembly. The proximity may be controlled by finely machining the semiconductor pieces to precisely fit closely together, such as by machining the edges of semiconductor wafers to minimize the gap between adjacent pieces. For example, the semiconductor wafer, or the boule itself, may be shaped, such as by machining, from a circular shape (cylindrical in the case of the boule) to a rectangular shape so that that the individual tiles may be fitted closely.

In one approach to the tiling operation, pieces of one or more semiconductor wafers may be assembled in a desired pattern and then bonded to a conductive substrate which acts as a support structure. The bonding can be done by soldering, brazing, or use of a refractory conductive glue. The support structure may be a metal foil or other conductive substrate which can withstand the process temperature. The semiconductor pieces on the conductive substrate are then implanted with, for example, hydrogen ions, and anodic bonding to the glass or glass ceramic carried out. After separation of the semiconductor films from the bodies of the semiconductor pieces, the exposed exfoliation surfaces of the semiconductor pieces on the conductive substrate can be polished to remove surface roughness, and implanted again, whereupon, the bonding process with another glass or glass ceramic substrate can be repeated. In this way, the semiconductor pieces do not need to be reassembled each time an SOI structure is produced. Tiling using a conductive support is particularly useful when large area SOI structures are to be produced.

In accordance with an embodiment of the present invention and as depicted in FIG. 1, a conventionally formed semiconductor wafer 10 is ion implanted according to conventional methods to form a damage or separation zone 12. The semiconductor material can be a silicon-based semiconductor or any other type of semiconductor, such as, the III-V, II-IV, II-IV-V, etc. classes of semiconductors. The semiconductor is preferably in the form of a substantially single-crystal material. The word “substantially” is used in describing the semiconductor wafer to take into account that semiconductor materials normally contain at least some internal or surface defects either inherently or purposely added, such as lattice defects or a few grain boundaries. The word “substantially” also reflects the fact that certain dopants may distort or otherwise affect the crystal structure of the bulk semiconductor.

Separation zone 12 is formed using implantation/exfoliation techniques of the type currently known to those skilled in the art or which may be developed in the future. At present, the separation zone 24 is preferably formed using the hydrogen ion implantation techniques of the references discussed above. Other currently-known techniques can also be used to form the separation zone, such as co-implantation of hydrogen and helium ions or hydrogen and boron ions. Whatever technique is chosen, the semiconductor wafer needs to be separable into first and second parts at the separation zone.

Suitable implantation depths (i.e. the depth of separation zone 14) which may be used are typically in the range of 10 nm to 900 nm. In some embodiments, preferred depths are in the 200 nm to 900 nm range. In other embodiments, preferred depths are in the 500 nm to 900 nm range 500 nm. Implantation depth 6 can be thinner than 10 nanometers, however excessively thin semiconductor layers will generally not provide sufficient material for the production of semiconductor devices. Thinner semiconductor layers may be created via oxidation or other methods known in the art.

Typically, ion implantation depth 6 is only a very small fraction of the total thickness of the semiconductor wafer. Portion or portions 16 of semiconductor wafer 10 on the side of the wafer closest to the damage/separation zone are then removed, leaving a raised portion of semiconductor—land portion 18. Portions 16 may be removed by such methods as photo-lithography, sub aperture deterministic and selective polishing, sub-aperture machining by plasma assisted chemical etch, etc. Land portion 18 is preferably rectangular, but may be other shapes as required for tiling. For example, land portion 18 could be octagonal. However, a rectangular shape, as best shown in FIG. 2, is the most efficient shape for the purpose of tiling on rectangular display substrates. The exposed surface 14 of land portion 18 will become bonding surface 14 of semiconductor wafer 10.

Once semiconductor portions 16 have been removed to form land portion 18, wafer 10 is cleaned, and surface 14 of land portion 18 is positioned proximate to and substantially parallel with bonding surface 24 of glass substrate 22. Taking into account that there may be some slight angle, e.g., up to 1-2 degrees, between surface 24 of glass substrate 22 and surface 14 of land portion 18, the surfaces are described herein as being “substantially parallel” which includes both the completely parallel and slightly angled cases. The phrase “substantially parallel” also includes the possibility that one or more of the surfaces or the separation zone may not be completely flat.

In order to ensure that the SOI structure has uniform properties in, for example, the radial direction for a circular wafer, e.g., uniform bonding strength at the interface between the semiconductor material and the glass substrate, any deviations from parallel of external surfaces 14, 24 and separation zone 12 are preferably kept to a minimum.

Substrate 22 preferably comprises an oxide glass or an oxide glass-ceramic; although not required, the embodiments described herein include an oxide glass or glass-ceramic exhibiting a strain point of less than 1,000° C. As is conventional in the glass making art, the strain point is the temperature at which the glass or glass-ceramic has a viscosity of 10^{14.6} poise (10^{13.6} Pa·s). As between oxide glasses and oxide glass-ceramics, the glasses are presently preferred because they are typically simpler to manufacture, thus making them more widely available and less expensive.

As shown in FIG. 3, substrate 22 has a thickness D, which is preferably in the range of 0.1 mm to 10 mm and most preferably in the range of 0.5 mm to 1 mm. For some applications of SOI structures, insulating layers having a thickness greater than or equal to 1 micron are desirable, e.g., to avoid parasitic capacitive effects which arise when standard SOI structures having a silicon/silicon dioxide/silicon configuration are operated at high frequencies. In the past, such thicknesses have been difficult to achieve. In accordance with the present invention, an SOI structure having an insulating layer thicker than 1 micron is readily achieved by simply using a substrate 22 whose thickness is greater than or equal to 1 micron. A preferred lower limit on the thickness of the substrate 22 is thus 1 micron.

In general terms, substrate 22 needs to be thick enough to support semiconductor wafer 10 through the process steps of the invention, as well as subsequent processing performed on the SOI structure. Although there is no theoretical upper limit on the thickness of substrate 22, a thickness beyond that needed for the support function or that desired for the ultimate SOI structure is generally not preferred since the greater the thickness of the substrate, the lower the electric field strength within the substrate during step for the same applied voltage difference.

The oxide glass or oxide glass-ceramic is preferably silica-based. Thus, the mole percent of SiO₂ in the oxide glass or oxide glass-ceramic is preferably greater than 30 mole % and most preferably greater than 40 mole %. In the case of glass-ceramics, the crystalline phase can be mullite, cordierite, anorthite, spinel, or other crystalline phases known in the art for glass-ceramics. The glass phase of the glass-ceramic should be sufficient to allow movement of positive ions away from the interface between the semiconductor wafer and the glass substrate during the bonding process.

Non-silica-based glasses and glass-ceramics can be used in the practice of the invention, but are generally less preferred because of their higher cost and/or inferior performance characteristics. Similarly, for some applications, e.g., for SOI structures employing semiconductor materials that are not silicon-based, substrates 22 which are not oxide based, e.g., non-oxide glasses, may be desirable, but are generally not preferred because of their higher cost.

For certain applications, e.g., display applications, the glass or glass-ceramic is preferably transparent in the visible, near UV, and/or IR wavelength ranges, e.g., the glass or glass ceramic is preferably transparent in the 350 nm to 2 micron wavelength range.

The glass or glass-ceramic of substrate 22 can be produced from conventional raw materials using a variety of techniques known in the glass making art.

The oxide glass or oxide glass-ceramic comprises at least some positive ions which during the bonding process move within substrate 22 in the direction of the applied electric field, i.e., away from surface 24 and towards surface 30. Alkali ions, e.g., Li⁺¹, Na⁺¹, and/or K⁺¹ ions, are suitable positive ions for this purpose because they generally have higher mobilities than other types of positive ions typically incorporated in oxide glasses and oxide glass-ceramics, e.g., alkaline-earth ions. However, oxide glasses and oxide glass-ceramics having positive ions other than alkali ions, e.g., oxide glasses and oxide glass-ceramics having only alkaline-earth ions, can be used in the practice of the invention.

The concentration of the alkali and alkaline-earth ions can vary over a wide range, representative concentrations being between 0.1 and 40 wt. % on an oxide basis. Preferred alkali and alkaline-earth ion concentrations are 0.1 to 10 wt. % on an oxide basis in the case of alkali ions, and 0-25 wt. % on an oxide basis in the case of alkaline-earth ions.

Although substrates 22 composed of a single glass or glass-ceramic are preferred, laminated structures can be used if desired. When laminated structures are used, the layer of the laminate closest to the semiconductor wafer should have the properties discussed herein for a substrate 22 composed of a single glass or glass-ceramic. Layers farther from semiconductor wafer 10 preferably also have those properties, but may have relaxed properties because they do not directly interact with the semiconductor material of wafer 10. In the latter case, the substrate 22 is considered to have ended when the properties specified for substrate 22 are no longer satisfied.

Along these same lines, either or both of semiconductor wafer 10 and glass substrate 22 can include surface layers over part or all of their external surfaces, e.g., an oxide layer on the semiconductor. When present on surface 14 of semiconductor wafer 10 and/or surface 24 of substrate 22, such surface layers should not have a composition and/or a thickness which will prevent the formation of a strong bond between wafer 10 and substrate 22. In particular, an oxide layer on the semiconductor wafer having a thickness greater than about 100 nanometers can lead to weak or no bonding with the glass or glass-ceramic substrate.

Although not wishing to be bound by any particular theory of operation, it is believed that an oxide layer having a greater thickness provides a high resistance to current flow and thus diminishes the electrolysis-type reaction at the interface between the semiconductor wafer 10 and substrate 22 which is believed to produce the desired strong bond. Accordingly, when an oxide layer is present on the bonding surface of semiconductor wafer 10, it should function primarily as a passivation layer, as opposed to an insulating layer. Likewise, any oxide layer formed on bonding surface 24 of substrate 22 should not interfere with current flow and thus will typically (and preferably) have a thickness of less than about 100 nanometers. When surface layers are present on the bonding surfaces of semiconductor wafer 10 and/or substrate 22, they constitute intermediate layers between semiconductor wafer 10 and substrate 22 in the finished SOI structure.

For certain wafer/substrate combinations, pretreatment of the bonding surface 14 of semiconductor wafer 10 to reduce its hydrogen concentration has been found advantageous in achieving bonding of land portion 18 of semiconductor wafer 10 to substrate 22. In particular, such a reduction in hydrogen concentration has been found to be of particular importance when transferring silicon films from silicon wafers implanted with hydrogen ions to glass substrates containing alkaline-earth ions, such as, substrates made of Corning Incorporated Glass Composition No. 1737 or Corning Incorporated Glass Composition No. EAGLE 2000™, which are used in, for example, the production of liquid crystal displays. It is believed that a reduction in hydrogen concentration will also be advantageous for glass and glass ceramics having high strain points, e.g., in the 850° C. to 900° C. range, which are expected to be needed for RF applications in wireless and other electronics applications.

In particular, it has been found that after hydrogen ion implantation, the surface of an implanted silicon wafer has a high hydrogen concentration, e.g., a high hydrogen ion concentration. The hydrogen termination at the Si surface inhibits the bonding process and thus it has been found desirable to reduce the hydrogen concentration on the implanted Si wafer surface by using a gentle oxidizing treatment in order to obtain effective Si layer transfer to glass substrates of the foregoing types. Reduction in hydrogen concentration results in making the implanted silicon wafer more hydrophilic and allows the bonding to take place during the application of voltage and heat. The strong bond formed during the process allows uniform separation of the Si film from the mother wafer.

Quantitatively, it has been found that in the absence of a hydrogen reduction treatment, only about 10% of the glass substrate is covered with a Si film and even in the covered area, the Si film tends to be non-uniform. However, when the hydrogen concentration at the surface of the Si is reduced by an oxidizing treatment, a uniform Si film becomes attached to the glass substrate over its entire surface.

Various approaches can be used to reduce the hydrogen concentration on the surface of an implanted wafer. Preferred approaches involve a mild oxidation treatment of the surface, such as, treatment of the wafer with an oxygen plasma, treatment with hydrogen peroxide, hydrogen peroxide and ammonia, hydrogen peroxide and ammonia followed by hydrogen peroxide and an acid, or combinations of these processes. Treatment with an oxygen plasma is the preferred approach, especially in a commercial setting. Although not wishing to be bound by any particular theory of operation, it is believed that during these treatments, hydrogen terminated surface groups oxidize to hydroxyl groups, which in turn makes the surface of the silicon wafer hydrophilic. The treatment is preferably carried out at room temperature for the oxygen plasma and at a temperature between 25-100° C. for the ammonia+peroxide or ammonia+peroxide followed by acid+peroxide treatments.

Although the foregoing discussion has been in terms of silicon wafers, it is believed that reductions in hydrogen concentration will be advantageous for hydrogen-implanted semiconductor wafers composed of semiconductor materials other than silicon.

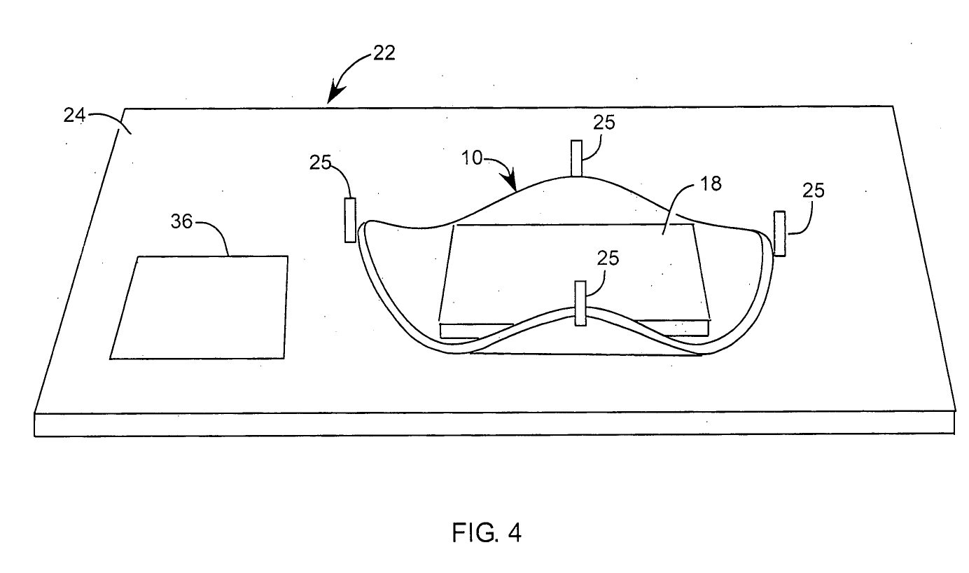

Turning to FIGS. 3-4, these figures represent the process of the invention in which semiconductor wafer 10 and substrate 18 are brought into contact at their bonding surfaces 14 and 24, respectively. In one embodiment of the present invention, wafer 10 is suspended slightly above substrate 22 with surface 14 proximate to and substantially parallel with surface 24 as previously described. Wafer 10 is suspended, for example, by supporting edges of wafer 10 with edge retainer or retainers 25. For example, four edge retainers 25 may be used, and positioned at the cardinal points of the wafer edge. That is, positioned about the circumference of the wafer with equal angular separation (e.g. 0°, 90°, 180° and 270°). Although a discrete retainer is shown in FIG. 3, retainer 25 may be a clamping mechanism which encircles the circumference of wafer 10. Various other configurations and mechanisms as are known may be used to secure and/or retain edges of the wafer in a fixed position relative to surface 24 of substrate 22, as appropriate. The separation between surface 14 and surface 24 prior to the pressing need not be large, and in some embodiments may be less than about 10 μm. Heater 26 is then pressed down on backside surface 28 of wafer 10, forcing surface 14 of land portion 18 into contact with surface 24 of substrate 22. It is desirable that heater/electrode 26 have the same size and shape as the land portion 18 of substrate 22, and aligned precisely to land portion 18 while pressing land portion 18 against substrate 22.

In preferred embodiments of the invention, semiconductor wafer 10 and substrate 22 may be heated prior to contacting, e.g., heated so that backside surfaces 28 and 30 are at T₁ and T₂, respectively. In this way, differential expansion between semiconductor wafer 10 and substrate 22 is avoided during the bonding process. Alternatively, semiconductor wafer 10 and substrate 22 may be left unheated prior to contacting, but may be heated after bonding surfaces 14 and 24 have been brought into contact and before the beginning of applying a voltage between semiconductor wafer 10 and substrate 22, and/or during applying a voltage before substantial bonding has occurred. When pre-heating is performed, the bonding surfaces can be separated by spacers that are removed once the desired temperatures of semiconductor wafer and substrate 22 have been reached.

The processing chamber for conducting the bonding (not shown) can have a variety of configurations. For experimental purposes, a bonder of the type sold by Süss Microtec of Munich, Germany, can be used as the processing chamber. The same equipment can be used for commercial applications, although equipment capable of simultaneously processing multiple wafer/substrate assemblies will generally be preferred.

Because the invention uses low to moderate temperatures, pressures, electric field strengths, and vacuum levels, the requirements which the processing chamber needs to satisfy are not demanding, which is another important advantage of the invention, i.e., the invention can be practiced with equipment which is both relatively inexpensive and widely available or easily fabricated for custom applications.

The bonding process (e.g. application of voltage, pressure and temperature, represented by arrows 32) is performed for a period of time sufficient for semiconductor wafer bonding surface 14 and substrate bonding surface 24 to bond to one another. For example, bonding can be performed for a period between 45 and 90 minutes. Shorter periods of time are, of course, generally preferred (e.g., times less than 30 minutes) and in a commercial setting, it is expected that the time required to bond semiconductor wafer 10 and substrate 22 can be reduced to a period of 5-15 minutes or less through the optimization of substrate materials, processing temperatures, and applied voltages.

Bonding of the wafer and the substrate is preferably performed under moderate vacuum conditions in the chamber wherein the bonding occurs. Preferably, the pressure in the chamber is less than or equal to 1 millibar, and most preferably, less than or equal to 10⁻³ millibars. Alternatively, the bonding process can be performed in an inert atmosphere, such as an atmosphere of argon, helium, or the like.

As discussed above and shown in FIG. 3, bonding is performed with V₁>V₂ and preferably with T₁<T₂, where V₁ and T₁ are, respectively, the voltage and temperature at surface 28, and V₂ and T₂ are, respectively, the voltage and temperature at surface 30.

V₁ and V₂ preferably satisfy the relationship:
100 volts/cm≦(V₁−V₂)/D≦40 kilovolts/cm,
where D is the distance between the surfaces 28, 30 during bonding. A preferred value for the (V₁−V₂)/D ratio ranges between about 5-20 KV/cm.

T₁ and T₂ preferably satisfy the relationships:
Tₛ−350≦T₁≦Tₛ+350; and
Tₛ−350≦T₂≦Tₛ+350;
where Tₛ is the strain point of the oxide glass or oxide glass-ceramic and Tₛ, T₁, and T₂ are in degrees centigrade. As discussed above, Tₛ is less than 1000° C., can be less than 800° C., and may also be less than about 700° C.

Typically, both T₁ and T₂ will be greater than or equal to 300° C. and less than or equal to 800° C., although higher or lower temperatures can be used, if desired. Within this range, lower temperatures are generally preferred, e.g., temperatures of around 450° C. for glasses like Corning Incorporated Glass Composition Nos. 7070 and 7740.

In addition to their role in achieving bonding of semiconductor wafer 10 and substrate 22, as discussed above, T₁ and T₂ are chosen to provide differential contraction of the first and second substrates upon cooling so that in the preferred embodiments of the invention, the substrate 22 seeks to contract to a greater extent than wafer 10 to thereby weaken wafer 10 at separation zone 12 and produce an SOI structure where the semiconductor film is under compression, as opposed to tension. Typically and preferably, T₂ will be greater than T₁, with T₁ and T₂ generally satisfying the relationship:
5° C.≦T₂−T₁≦150° C.,
and preferably the relationship:
10° C.≦T₂−T₁≦150° C.

Moreover, the coefficients of thermal expansion of wafer 10 and substrate 22 and the chosen temperature differential will preferably satisfy at least one and most preferably both of the following relationships:
CTE₁−20×10⁻⁷/° C.≦CTE₂≦CTE₁+20×10⁻⁷/° C.; and/or
(T₂−T₁)·|CTE₂−CTE₁|≦30×10⁻⁵, T₂>T₁;
where CTE, is the 0° C. coefficient of thermal expansion of the substantially single-crystal semiconductor material and CTE₂ is the 0-300° C. coefficient of thermal expansion of the oxide glass or oxide glass-ceramic. In applying these relationships, the 0-300° C. CTE of the oxide glass or oxide glass-ceramic (i.e., CTE₂) preferably satisfies the relationship:
5×10⁻⁷/° C.≦CTE₂≦75×10⁻⁷/° C.

After bonding surfaces 14 and 24, the bonded semiconductor wafer 10 and substrate 22 are cooled, e.g., to room temperature, and land portion 18 is separated from the remainder of wafer 10, i.e. portion 34. Because of the weakening of the separation zone 12 which occurs during cooling, separation can be performed without disturbing the bond between land portion 18 and substrate 22, or damaging land portion 18 or substrate 22. In many cases, the separation involves merely releasing the force on wafer backside surface 28, since during the cooling, land portion 18 may become completely free of wafer portion 34. Because wafer 10 is substantially rigid and elastic, the flexure created in wafer 10 by restraining the edges and applying a force to the backside, also creates an elastic restoring force. When the force applied to the backside of wafer 10 is removed, the restoring force may be sufficient to separate land portion 18 from the remainder of wafer 10. In some cases, a slight peeling action, like that used to remove household plastic wrap from a smooth object, may be used at the end of the cooling to separate the two parts (18, 34), but more than this is not needed because of the differential contraction of wafer 10 and substrate 22 and the resulting weakening of the separation zone.

Separation of land portion 18 from wafer portion 34 will typically result in part of separation zone 12 ending up associated with land portion 18 and part ending up associated with the remainder of wafer portion 34. Depending upon processing conditions and ultimate end use, the exposed external surfaces of land portion 18 and wafer portion 34 produced by this separation, i.e., the exfoliation surfaces, may be useable as is or may require subsequent treatments, e.g., polishing, etching, doping, etc., prior to use. For example, prior to reuse as a donor wafer in another iteration of the overall process, the exfoliation surface of wafer portion 34 may be subjected to conventional contact polishing (e.g. chemical mechanical polishing) to provide a sufficiently smooth surface for bonding to a new substrate. Such polishing or other surface treatments may also be appropriate for the exfoliation surface of the bonded land portion 18 prior to its use in the manufacture of a thin film transistor or other electronic device.

Although generally not preferred, one can conceive of partially cooling wafer 10 and substrate 22 and then applying a separating force, e.g., twisting the wafer and the substrate relative to one another, while continuing to subject the wafer and substrate to an elevated temperature, an electric field, and an applied pressure. Such separating can, for example, be begun part way through the bonding process.

As noted above, once land portion 18 is separated from the remainder of wafer 10, the resulting SOI structure, i.e., land portion 18 and attached substrate 22, can be subjected to further processing as appropriate for the intended use of the structure. In particular, the exposed exfoliation surface of bonded portion 18 can, for example, be treated to remove any roughness or other imperfections arising from the separation process. Similarly, the exposed exfoliation surface of wafer portion 34 can be treated for subsequent use as, for example, a new (slightly thinner) wafer.

It should be apparent to one skilled in the art that the process described supra may be repeated many times. That is, a semiconductor wafer is ion implanted, a portion of the wafer is removed to leave a raised portion, the raised portion then being bonded to a substrate by restraining the edges of the wafer and pressing down on the backside of the wafer to contact the raised portion with the substrate while applying pressure, voltage and heat, then separating the wafer along the defect boundary created by the ion implantation. The wafer may then be reused by polishing the wafer at the exfoliation surface, again ion implanting the wafer, and processing as before. Thus, the present invention may be used to tile the surface of substrate 22 as described supra and as best shown in FIG. 4. Although FIG. 4 shows the separation between the previously bonded semiconductor film 36 and a semiconductor film being newly bonded as large, this distance is only for clarity. In practice it would be preferable that each portion of semiconductor film bonded to and exfoliated onto the substrate is closely fit to a preceding semiconductor film piece (e.g. film 36 depicted in FIG. 4) to minimize gaps between the pieces. In addition, one the substrate has been covered with silicon film pieces, the surface of the silicon film may be polished, if desired, to insure smoothness and/or thickness of the film. If necessary, gaps may be filled according to conventional methods prior to polishing.

It should be emphasized that the above-described embodiments of the present invention, particularly any “preferred” embodiments, are merely possible examples of implementations, merely set forth for a clear understanding of the principles of the invention. Many variations and modifications may be made to the above-described embodiments of the invention without departing substantially from the spirit and principles of the invention. All such modifications and variations are intended to be included herein within the scope of this disclosure and the present invention and protected by the following claims.

What is claimed is:

1. A method of forming a semiconductor film on a substrate comprising:
providing a semiconductor wafer;
ion implanting the semiconductor wafer;
removing portions of the semiconductor wafer to form a raised portion on the wafer;
bonding the raised portion of the wafer to the substrate;
separating the raised portion from the wafer to form the semiconductor film on the substrate.

2. The method according to claim 1 wherein the bonding comprises restraining edges of the wafer and pressing the raised portion into contact with the substrate.

3. The method according to claim 2 wherein the restraining comprises restraining the wafer edges at equal angular spacing about a circumference of the wafer.

4. The method according to claim 1 wherein the raised portion is rectangular.

5. The method according to claim 1 wherein the bonding is anodic bonding.

6. A method of forming a semiconductor film on a glass substrate comprising:
forming a separation zone in a semiconductor wafer;
removing a portion of the semiconductor wafer to form a raised portion on the wafer;
anodically bonding the raised portion to the glass substrate;
separating the raised portion from the wafer; and
wherein the bonding comprises restraining an edge of the wafer and pressing the raised portion into contact with the substrate.

7. The method according to claim 6 further comprising heating the wafer and the substrate prior to the bonding.

8. The method according to claim 6 wherein the semiconductor wafer comprises silicon.

9. The method according to claim 6 wherein the removing comprises a method selected from the group consisting of photo-lithography, sub-aperture deterministic and selective polishing, and sub-aperture machining by plasma assisted chemical etch.

10. The method according to claim 6 wherein the forming a separation zone comprises implantation of ions selected from the group consisting of hydrogen, helium, boron and combinations thereof.

11. The method according to claim 6 further comprising tiling the surface of the substrate with semiconductor films.

12. A semiconductor on insulator structure made by the method of claim 6.

13. A method for forming an SOI structure comprising:
a. providing a circular semiconductor wafer having at least one substantially planar first surface and a second surface opposite the first surface;
b. forming a defect boundary within the wafer at a predetermined depth from the wafer first surface by ion implantation;
c. removing material from the wafer such that a raised, rectangular region is formed on the first surface of the wafer;
d. positioning the wafer over a planar substrate such that a surface of the raised rectangular region is substantially parallel with a surface of the substrate;
e. restraining an edge of the wafer;
f. contacting the raised rectangular region with the silicon wafer by forcing a heater plate against the wafer second surface;
g. bonding the raised rectangular region to the substrate by anodic bonding;
h. separating the wafer along the defect boundary, thereby forming a semiconductor layer on the substrate.

14. The method according to claim 13 wherein the semiconductor comprises silicon.

15. The method according to claim 13 wherein the substrate is a glass or glass-ceramic.

16. The method according to claim 13 further comprising repeating steps b. through h. to tile the substrate with semiconductor layers.

17. The method according to claim 16 further comprising, prior to repeating steps b. through h., polishing the wafer first surface.

18. The method according to claim 16 further comprising polishing the tiled semiconductor layers.

19. The method according to claim 13 wherein the restraining comprises restraining the wafer edge at equal angular spacing about a circumference of the wafer.

20. A semiconductor on insulator structure made by the method of claim 13.
